(19) United States
(12) Patent Application Publication
(10) Pub. No.: US 2008/0024962 A1
(43) Pub. Date: Jan. 31, 2008

(54) Electronic device shell providing waterproofing and non-screw functions

(76) Inventors: Bily Wang, Hsinchu City (TW); Chun-Tsai Pan, Jhudong Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/878,339

(22) Filed: Jul. 24, 2007

(30) Foreign Application Priority Data
Jul. 31, 2006 (CN) 200610108180.0

(51) Int. Cl. H05K 5/02

(52) U.S. Cl. 361/679

(57) ABSTRACT

An electronic device shell providing waterproofing and non-screw functions includes a first shell, a second shell, and a waterproof ring. The first shell covers the second shell via the waterproof ring. Via the fixing structure of the fist shell and the second shell, the waterproof ring is pressed tightly against the fist shell and the second shell. Thus, waterproofing and non-screw functions are provided.

### BACKGROUND OF THE INVENTION

1. Field of the Invention

The present invention relates to an electronic device shell providing waterproofing and non-screw functions, and in particular to use of a waterproof ring and retaining structures of the shell to provide the function of waterproofing.

2. Description of Related Art

Referring to FIG. 1, a Global positioning system (GPS) shell providing a waterproofing function is shown. The shell has a first shell 1a, a second shell 2a and a waterproof ring 3a. The first shell 1a covers the second shell 2a via the waterproof ring 3a. A strong pressure between the first shell 1a and the second shell 2a is needed for pressing the waterproof ring 3a. Therefore, a plurality of screws 4a are used to fix the first shell 1a and the second shell 2a together. However, the speed of production is slowed by the action of screwing, and the screws 4a will rust after a period time. The first shell 1a has a frame 13a extending from the top surface of the first shell. A magnet 5a is put into the frame 13a, but the frame 13a lacks a fixing structure. A traditional method for resolving this problem is coating glue on the magnet 5a to improve adhesion with the frame 13a. Thereby, the magnet 5a is prevented from being pulled away from the frame, when other magnetic components are placed near it. Thereby resolving problems that occur during fabrication, and eliminating the time for wasted waiting for the glue to dry.

The waterproof material of the prior art is rubber that is hard in conditions above 40 degrees. Thereby, when the shells are combined with retaining structures, rather than screws, the shells will be separated by a small impact hit, such as when the object falls to the ground.

The other method involves the joint between the first shell 1a, the second shell 2a and the waterproof ring 3a being adhered by glue, rather than being fixed together by screws. However, when the glue is coated uneven, a gap is produced and the waterproofing function is poor. On the other hand, when the glue overflows during the coating process, someone needs to clear it away. Moreover, time is wasted waiting for the glue to dry.

Thus, a new design for the shell is needed to overcome the defects as described above.

### SUMMARY OF THE INVENTION

It is an object of the present invention to provide an electronic device shell providing waterproofing and non-screw functions for quicker fabrication and better waterproofing.

It is another object of the present invention to provide a retaining structure for a magnet that can be fabricated faster.

To achieve the above objects, an electronic device shell providing waterproofing and non-screw functions is put forth. The electronic device shell comprises: a first shell having a plurality of first retaining elements; a waterproof ring corresponding to the first shell; and a second shell having a plurality of second retaining elements; wherein the second retaining elements fix to the first retaining elements respectively, and the second shell covers the first shell via the waterproof ring.

### BRIEF DESCRIPTION OF THE DRAWINGS

The present invention can be fully understood from the following detailed description and preferred embodiments with reference to the accompanying drawings, in which:

FIG. 1 is an exploded view of an electronic device shell according to the prior art;

FIG. 2 is an exploded view of an electronic device shell according to the present invention; and

FIG. 3 is a perspective view of an electronic device shell according to the present invention.

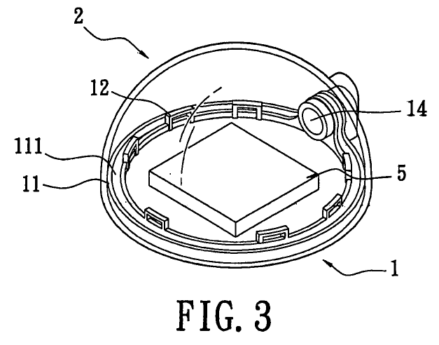

### DETAILED DESCRIPTION OF THE PREFERRED EMBODIMENTS

The following detailed description is of the best presently contemplated modes of applying the invention. This description is not intended to be taken in a limiting sense, but is made merely for the purpose of illustrating general principles of embodiments of the invention. The scope of the invention is best defined by the appended claims.

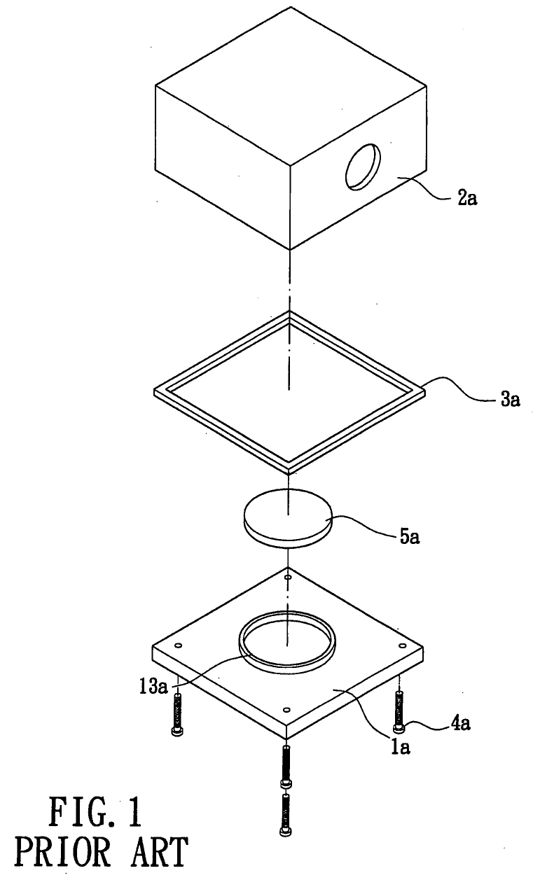

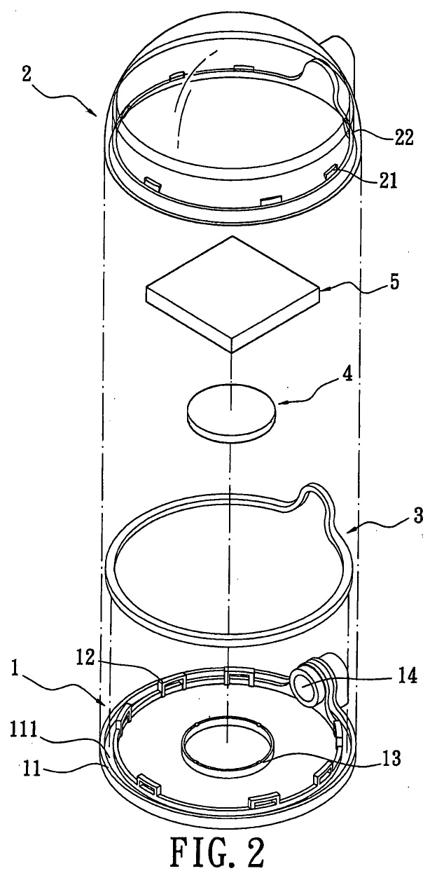

Reference is made to FIG. 1 and FIG. 2. An electronic device shell providing waterproofing and non-screw functions includes a first shell 1, a second shell 2, and a waterproof ring 3. A circular portion 11 is disposed around the top surface of the first shell 1. A circular groove 111 is disposed on the top of the circular portion 11. The waterproof ring 3 is disposed correspondingly in the groove 111. The waterproof ring 3 has a 3D structure corresponding to the shape of the surface of the groove 111 for better waterproofing function. The material of the waterproof ring 3 can be made of rubber or silica gel. The hardness of the waterproof ring 3 is between 10 and 40 degrees.

A plurality of first retaining elements 12 are disposed on a side or on the surrounding of the circular portion 11 of the first shell 1. The first retaining elements 12 and the first shell 1 are integrally formed. The first retaining elements 12 are fixing hooks or fixing grooves. At least five first retaining elements 12 have better fixing functions. A circular inner wall 21 is disposed around the inner surface of the second shell 2. The thickness of the inner wall 21 is less than or equal to the groove 111. A plurality of second retaining elements 21 are disposed on the side of the inner wall 21. The second retaining elements 21 and the inner wall 21 are integrally formed. The second retaining elements 21 are fixing grooves or fixing hooks, which correspond to the first retaining elements 12. The second shell 2 covers the first shell 1 via the waterproof ring 3. The first retaining elements 12 of the first shell 1 are retained to the second retaining elements 22 of the first shell 2 respectively to make the top surface of the inner wall 21 of the second shell 2 press against the waterproof ring 3.

Thereby, the function of the waterproof ring is achieved without screws. When assembling the product, the first shell and second shell are simply attached together. Because the step of screwing is omitted, assembly time is reduced and the problem of poor adhesion due to rusted screw is avoided. Because the glue is excluded, time waiting for the glue to dry is excluded and leaking via the gap when the glue is coated unevenly is prevented.

The first retaining elements 12 and the second retaining elements 22 are combined to form a retaining structure. Any retaining structure is included in the scope of the present invention. In another embodiment, the edge of the second shell 2 covers the first shell 1 via the waterproof ring 3. The second retaining elements 22 are disposed on the sidewall of the second shell 2. This means that the inner wall 21 is excluded. The groove 111 is disposed on the top surface of the first shell 1 directly, and the first retaining elements 12 are disposed on the periphery of the groove 111.

The present invention is applied to a global positioning system (GPS). A circular frame 13 is disposed on the inner top surface of the first shell 1. The top of the frame 13 is extended inward. The circular frame 13 has a groove for retaining a magnet 4 therein. Thereby, the step of gluing the magnet 4 to the circular frame 13 is excluded, and the time waiting for the glue to dry is excluded. A control unit 5 is disposed on the top surface of the first shell 1. A hole 14 is disposed on a side of the first shell 1 for a connector line to pass through and connect to the control unit 5.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. An electronic device shell providing waterproofing and non-screw functions, comprising:
a first shell having a plurality of first retaining elements;
a waterproof ring corresponding to the first shell; and
a second shell having a plurality of second retaining elements;
wherein the second retaining elements fix to the first retaining elements respectively, the second shell covers the first shell via the waterproof ring.

2. The electronic device shell as claimed in claim 1, wherein the first retaining elements are fixing hook or fixing grooves.

3. The electronic device shell as claimed in claim 1, wherein the second retaining elements are fixing grooves or fixing hooks.

4. The electronic device shell as claimed in claim 1, wherein a circular portion is disposed around the top surface of the first shell, a circular groove is disposed on the top of the circular portion, and the waterproof ring is disposed correspondingly in the groove.

5. The electronic device shell as claimed in claim 1, wherein a circular groove is disposed around the top surface of the first shell, and the waterproof ring is disposed correspondingly in the groove.

6. The electronic device shell as claimed in claim 5, wherein the waterproof ring has a 3D structure that corresponds with the surface of the groove.

7. The electronic device shell as claimed in claim 1, wherein the waterproof ring comprises a material selected from a group consisting of rubber or silica gel.

8. The electronic device shell as claimed in claim 1, wherein the waterproof ring has hardness between 10 and 40 degrees.

9. The electronic device shell as claimed in claim 1, wherein the inner surface of the second shell has a circular inner wall for creating pressure onto the waterproof ring 3.

10. The electronic device shell as claimed in claim 1, wherein the first shell has a frame, and the top of the frame extends inward.

11. The electronic device shell as claimed in claim 1, wherein a side of the first shell has a hole.
